(19) United States
(12) Patent Application Publication
(10) Pub. No.: US 2026/0265948 A1
(43) Pub. Date: Sep. 10, 2026

(54) PROCESS FOR PRODUCING SINGLE CRYSTAL-LIKE SILVER FILMS

(71) Applicant: University of South-Eastern Norway, Borre (NO)

(72) Inventors: Kim Robert GUSTAVSEN, Borre (NO); Kaiying WANG, Borre (NO)

(73) Assignee: University of South-Eastern Norway, Borre (NO)

(21) Appl. No.: 18/873,558

(22) PCT Filed: Jun. 19, 2023
(86) PCT No.: PCT/NO2023/050143

§ 371 Date: Dec. 10, 2024

(30) Foreign Application Priority Data
Jun. 21, 2022 (NO) 20220708

(51) Int. Cl. C30B 23/02; C23C 14/14; C23C 14/34; C23C 14/35; C30B 29/02

(52) U.S. Cl. CPC C30B 23/02; C23C 14/14; C23C 14/3464; C23C 14/352; C30B 29/02

(57) ABSTRACT

The invention relates to a process for deposition of single crystal-like silver thin films on a substrate and corresponding processing unit. The process involves a sputtering method for depositing silver on a substrate using a DC sputtering method, and wherein the process also includes a RF powered boron deposition, the RF and silver deposition being performed simultaneously.

The present invention is related to the production of single crystal-like thin film, especially silver thin films using sputtering techniques.

Single crystal-like metal thin films are highly desirable for their unique material properties in microelectronics and for optical application due to the surface plasmonic resonance effect. Silver is considered to be the best plasmonic metal at optical and near infrared frequencies. However, the surface plasmonic resonance must be manipulated for the application in devices. Such manipulation is often accomplished by patterning the metal layer by a focused-ion- milling (FIB). Unfortunately, FIB is an anisotropic process where each crystal plane etches away at different rates, giving rise to increased roughness and large surface irregularities, significantly increasing loss due to surface plasmonic scattering. Therefore, to ensure precise patterning, single crystal or single crystal-like silver thin films are ideal as it provides a uniform etch rate across the film surface. The term single crystal-like silver thin films includes single crystal silver thin films as well as similar materials such as epitaxial silver films as disclosed in the article by D. Bufford et al, “High strength, epitaxial nanotwinned Ag films”, Acta Materialia 59 (2011) 93-101, doi: 10.1016/j.actamat.2010.09.011

The growth of single crystal-like silver thin films is challenging and requires stringent growth conditions, and often lacks thickness control, which is crucial for plasmonic devices. Usually, single crystal-like silver thin films are attained by epitaxial growth. Epitaxial growth is where a single crystal-like thin film is achieved by depositing the desired material onto a specific substrate or seed-layer of a certain crystal orientation. Typical deposition methods for epitaxial growth are molecular beam epitaxy (MBE), atomic layer deposition (ALD), and epitaxial chemical vapour deposition (CVD), where the deposition rates are very low, limiting the attainable film thickness. Successful single crystal-like silver thin film growth has been achieved by DC sputtering and high deposition rate e-beam, but similar to the forementioned techniques it uses epitaxial growth, where a specified substrate or seed-layer is needed, and where substantial substrate temperature is required during growth or when post-annealing. Japanese patent application JPH04116163 describes an example of a method for producing a single crystal silver film by ion beam sputtering on a Si or Mg substrate.

In this invention, a process is described for deposition of single crystal-like silver thin films using magnetron sputtering at room temperature that differs from conventional epitaxial growth. Magnetron sputtering is a physical vapor deposition (PVD) technique that similar to regular sputtering utilizes plasma to deposit a material onto a substrate. It differs from traditional sputtering, by employing magnets which traps the electrons from the local electric field near the target surface, thereby significantly increasing the deposition rate. Sputtering is generally used for depositing polycrystalline metal thin films but can also deposit thin films of insulators or other compounds by RF power.

Magnetron sputtering is an industrial tool capable of large-scale fabrication and is not limited in terms of substrate size. It has relatively high deposition rate compared to the epitaxial growth methods and can be easily scaled up for large-scale production. Without the requirement of a specific substrate and with single crystal-like growth being attainable at room temperature, it makes it an ideal process for microfabrication, meaning that it is compatible with microelectronics for instance for optical devices. Another big advantage is that the single crystal-like films are continuous over the entire substrate, in our case over a 4″ wafer, but the process should be easily scalable to 6″ wafers.

It is also known that co-sputtering of different materials may be used to produce films of different compositions such as silver-boron-films, as is described in Oren Metz et al: “Ag-B Thin Films Prepared by Magnetron Sputtering”, Mater. Res. Soc. Symp. Proc Vol. 848, 2005 Material Science Society. The article applies RF power to both the B and Ag target (we use DC for Ag). In addition, the power applied to the silver target is very low (20W) combined with a very high power for the B target (300W). The resulting films therefore contains high concentration of B, giving the AgB2 phase.

Another example of the prior art is discussed in Joshua Pelleg et al: Borides of Ag and Au prepared by magnetron sputtering”, Physica C 466 (2007) 61-64. In this paper they apply DC power to Ag and RF power to B similarly to our method. The DC power is in the range of 20-30W, and the RF power is set to 300W. The Boron concentration is very high compared to the silver (see table 1).

Single crystal-like silver thin films are highly attractive for optical, bio-catalytic, biological, and plasmonic applications. However, growing single crystal-like silver thin films with a high degree of thickness control and with a high deposition rate remains a challenge. Sputtering technology is a method that can provide moderately high deposition rate relative to other methods used for growing single crystal-like silver films; however, depositing single crystal-like silver through sputtering deposition, like other epitaxial deposition methods, has required a specific substrate material with a designated crystal orientation together with a high substrate temperature (>350° C.). These requirements have limited the application of sputtered single crystal-like silver thin films, as the substrate material, crystal orientation, or substrate temperature during deposition might not be compatible with the microfabrication process.

The present invention is aimed at providing catalyst materials for the electrochemical reduction of CO₂ into fuels, specifically the present invention is aimed at producing single crystal-like silver film on a substrate. The objectives of the invention are achieved as specified in the accompanying claims.

The objectives of the invention are thus achieved by using magnetron sputtering to synthesize metal thin-films with controllable concentration of impurities through an RF-assisted DC sputtering process. The sputtering process may be based on a confocal sputtering configuration as discussed in Hyon-Jong Kim, et al, “High-throughput analysis of thin-film stresses using arrays of micromachined cantilever beams”, Review of Scientific Instruments 79, 045112 (2008). DOI: 10.1063/1.2912826 In this way a process of depositing single crystal silver thin films has been provided that is not substrate-dependent, without thickness limitations, and can be synthesized at room temperature.

The invention will be described below with reference to the accompanying drawings, illustrating the invention by way of examples.

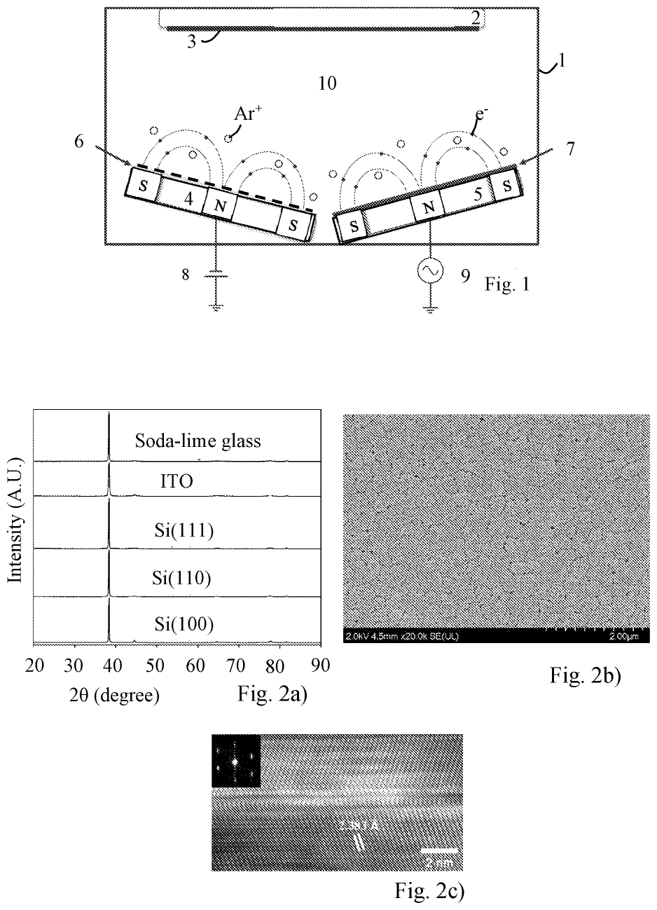

FIG. 1 illustrates schematically the sputtering system used according to the invention to synthesize the single crystal-like silver films.

FIGS. 2a-2c shows the properties of the produced material.

As is schematically illustrated in FIG. 1 the system according to the invention and/or for performing the invention comprises a chamber 1 containing an Ar⁺/e⁻ atmosphere 10 as is well known in the field. A substrate 2 is provided in the chamber having a surface toward the chamber on which the film 3 is deposited. The substrate may be of any suitable material, especially Si (100), Si (110), Si (111), ITO, soda-lime glass, chromium, or quartz.

As is shown the invention utilizes two source materials 6,7 in a confocal sputtering arrangement, being constituted by a silver target 6 and a Boron target 7, respectively. According to the invention the silver sputtering unit 4 is connected to a DC power source 8 driven at a predetermined voltage, while the boron sputtering unit 5 is driven by an RF source 9 driven at a chosen voltage and frequency. Using this, both silver and boron will be deposited at the substrate.. The distances from the targets 6,7 to the substrate 2 may depend on the chosen parameters in the range of 5-50 cm and the angle of the targets relative to the substrate may be in the range of 15-75 degrees.

According to a first example, single crystal-like silver growth from room temperature to 400° C. is accomplished at the following substrates: Si(100), Si(110), Si(111), Indium Tin Oxide (ITO) glass, soda-lime glass, and chromium. There are no clear limitations on the film thickness, with single crystal-like growth observed in the range of 25-2000 nm. Furthermore, a deposition has been achieved at a rate of ~17 nm/min, which is significantly higher than alternative methods for single crystal-like silver growth such as MBE and ALD. Thus, the method for single crystal-like growth of silver is independent of the substrate and deposition temperature.

The invention provides a method or process for depositing single crystal-like silver thin films by utilizing an RF-assisted DC sputtering process where silver is deposited using DC power and boron is introduced using an RF power source to facilitate single crystal-like growth of silver. The morphology and the ratio of crystal orientation can be controlled by adjusting deposition parameters such as DC and RF power, chamber pressure, and substrate temperature.

According to a preferred embodiment of the invention the coating layers are deposited using a magnetron sputtering system in a RF-assisted DC sputtering procedure where silver is deposited using DC power and boron is simultaneously introduced using an RF power source as illustrated in FIG. 1. Increasing the RF power of the boron target changes the crystal structure of the deposited silver thin film from polycrystalline to single crystal or crystal-like silver. The RF power density of the boron target can be tuned in the range of 0-6.6 W/cm², where >3.3 W/cm² gives full conversion into a single crystal structure. The RF frequency will typically be 13.56 MHz. The DC power density applied to the silver target was 4.9 W/cm² for the fully converted thin films. During the growth, a sputtering gas is introduced at a controlled flow rate to achieve a chamber pressure in the range of 0.52-0.65 Pa. Single crystal-like silver coating layers are attainable at room temperature and does not require the substrate to be heated during deposition. The process has been verified for deposition onto various substrates, such as Si(100), Si(110), Si(111), soda-lime glass, and indium-tin-oxide (ITO) glass, both with and without a Cr adhesion layer.

The resulting material has properties as illustrated in FIGS. 2a-2c.

FIG. 2a illustrates the X-ray diffraction spectrum (XRD) used to determine the crystal structure of the silver coating layers on various substrates. The samples deposited using RF power density of 3.3 W/cm² yields single crystal structure with a dominant Ag (111) peak. The morphology of the samples was investigated using a field-effect scanning electron microscope (FE-SEM), e.g. as shown in FIG. 2b showing an SEM image of the film deposited on soda-lime glass. A granular structure was observed for the pure Ag films, whereas a gradual change in the morphology was achieved when increasing the RF power, resulting in a ‘nano-brain’ or tentacle-like structure, as shown in FIG. 2b, at a RF power density of 3.3W/cm². The growth mechanism was investigated using high-resolution transmission electron microscope (HRTEM). Highly ordered growth of the silver film with a high density of twin boundaries was observed, one such twin boundary is shown in FIG. 2c, with FFT of the signal om the upper left. The lattice spacing is measured to be ~2.385 Å, slightly in the higher range of the expected value for silver (111), indicating a strained lattice. Twinned growth usually occurs for epitaxial growth using very high deposition rates in DC sputtering. However, twin boundaries tend to form when there is substantial amount of stress and strain in the lattice during or following the deposition process, which in our case could occur due to the incorporation of boron. Furthermore, the Fast Fourier Transform (FFT) image of one sidewall of the twin boundary (FIG. 2c inset) shows a pattern indicating existence of single crystal structure.

To summarize, the present invention relates to a process or processing method for deposition of single crystal-like silver thin films on a substrate. The process involves a sputtering method for depositing silver on a substrate using a DC sputtering method and simultaneously a RF powered boron deposition, where the sputtering depositions are preferably performed with per se known confocal magnetron sputtering arrangements.

According to a preferred embodiment of the invention the substrates are heated in the range of 20-400° C. during deposition. The DC power applied in the silver deposition may preferably be varied in the range of 2.45-7.35 W/cm², and the RF power in the boron deposition may preferably be varied in the range of 1.1-6.6 W/cm². The sputtering gas is preferably used to control the chamber pressure in the range of 0.27-2.67 Pa and may be introduced with flow rates in the range of 5-30 cm³/s (standard conditions 0° C. and 1.013 bar).

The parameters mentioned above, i.e. chamber pressure, DC and RF powers may be adjusted to provide deposition rates of 1.2-20 nm/min.

The target to substrate distance may be varied in the range of 5-50 cm and the targets angle to the substrate is varied in the range of 15-75 degrees.

Preferably the single crystal-like silver films grown using the process on a substrate constituted by Si (100), Si (110), Si (111), ITO, soda-lime glass, chromium, or quartz.

Thus, the processing unit according to the invention preferably includes a chamber containing an argon ion atmosphere and a substrate configured to receive the film, the unit also including a silver coated sputtering unit being driven by a DC power source and a boron sputtering unit driven by an RF power source. As stated above the processing unit is configured to heat the substrate during deposition to a temperature in the range of in the range of 20-400° C., the DC power preferably in the range of 2.45-7.35 W/cm² and the RF power may be in the range of 1.1-6.6 W/cm². The pressure in the chamber being in the range of 0.267-2.666 Pa and may be introduced with flow rates in the range of 5-30 cm³/s. The target to substrate distance may be varied in the range of 5-50 cm and the targets angle to the substrate is varied in the range of 15-75 degrees.

1. A process for deposition of single crystal-like silver thin films on a substrate, comprising:
depositing silver on a substrate using DC sputtering;
RF powered boron deposition; and
wherein the above steps are performed simultaneously.

2. The process of claim 1, wherein the substrates in claim 1 are heated in the range of 20-400° C. during deposition.

3. The process of claim 1, wherein the DC power is varied in the range of 2.45-7.35 W/cm²

4. The process of claim 1, wherein RF power is varied in the range of 1.1-6.6 W/cm²

5. The process of claim 1, wherein the sputtering gas is used to control the chamber pressure in the range of 0.267-2.666 Pa.

6. The process of claim 1, wherein the sputtering gas is introduced with flow rates in the range of 5-30 cm³/s.

7. The process of claim 3, wherein the parameters are varied to achieve deposition rates of 1.2-20 nm/min

8. The process of claim 1, wherein the target to substrate distance is varied in the range of 5-50 cm.

9. The process of claim 1, wherein the targets angle to the substrate is varied in the range of 15-75 degrees.

10. A processing unit for processing a single crystal-like silver thin film, the processing unit comprising:
a chamber containing an argon ion atmosphere and a substrate configured to receive the film:
a silver sputtering target driven by a DC power source; and
a boron sputtering target driven by an RF power source.
